(19) United States
(12) Patent Application Publication
(10) Pub. No.: US 2005/0061953 A1
(43) Pub. Date: Mar. 24, 2005

(54) Dual-function electroluminescent device and method for driving the same

(76) Inventors: Johannes Nicolaas Huiberts, Eindhoven (NL); Adrianus Sempel, Eindhoven (NL); Pieter Jacob Snijder, Eindhoven (NL); Henricus Franciscus Johannus Jacobus Van Tongeren, Eindhoven (NL); Coen Theodorus Hubertus Fransiscus Liedenbaum, Eindhoven (NL); Gerjan Franciscus Arthur Van De Walle, Eindhoven (NL)

Correspondence Address: Philips Electronics North America Corporation;Corporate Patent Counsel, PO Box 3001, Briarcliff Manor, NY, 10510, US

(21) Appl. No.: 10/498,766

(22) PCT Filed: Dec. 16, 2002
(86) PCT No.: PCT/IB02/05465

(30) Foreign Application Priority Data
Dec. 20, 2001 (EP) 01205043.1

(51) Int. Cl. H01L 31/00

(52) U.S. Cl. 250/214.1

(57) ABSTRACT

This invention relates to a method of driving a dual-function light-emitting and light-sensing device (5) comprising an organic electroluminescent layer (1), such as a polymer layer or a small molecule compound layer, which is sandwiched between a first and a second electrode (2,3), comprising the following steps:—applying, during a emission state (t1), a first emission signal (V1, J1) to said electroluminescent layer (1), said first signal being such that light is generated by and emitted from said electroluminescent layer (1), and—applying, during a sensing state (t2), a second driving signal (V2,J2) to said organic electroluminescent layer (1), said second driving signal being such that the power of said second driving signal has essentially a zero value for accurately detecting an electric current generated in said organic electroluminescent layer when said organic electroluminescent layer is hit by external light This invention also relates to a dual-function light-emitting and light-sensing device and applications thereof.

This invention relates to a method of driving a dual-function light-emitting and light-sensing device comprising an organic electroluminescent layer, such as a polymer layer or a small-molecule compound layer, which is sandwiched between a first and a second electrode. The invention also relates to a dual-function light-emitting and light-sensing device. Further, this invention relates to a plurality of applications for such a display.

Organic electroluminescent displays and devices are fairly recently discovered technologies that are based on the realization that certain organic materials such as, for example, certain polymers may be used as semiconductors in a light-emitting diode. These devices are very interesting due to the fact that the use of organic materials such as polymer materials makes these devices light, flexible, and comparatively inexpensive to produce.

Recently, it has also been discovered that such light-emitting devices may be used as a tool to measure incident light. Such a device has been described, for example, in the patent document U.S. Pat. No. 5,504,323. This document describes a light-emitting diode which has dual functions. When the organic polymer layer of the diode is positively biased, the diode functions as a light emitter, and when the layer is negatively biased, it functions as a photodiode. The negative bias preferably has a negative voltage being in the interval of 2.5 to 15 V. It is also described that, since the photosensitivity of the layer increases with the reverse bias voltage, it is preferred to have a quite large negative bias across the organic polymer layer in the photodiode mode.

However, the dual-function diode as described above has a number of drawbacks. To start with, the device as described in U.S. Pat. No. 5,504,323 exhibits a non-symmetric leakage current behavior around 0 V, and the leakage currents are therefore found to be unstable. Moreover, the application of a high negative voltage leads to an increase of the failure probability of the device, and the dark current is highly unstable as it is directly related to defects and short circuits through the organic electroluminescent layer. This leads to a poor signal-to-noise ratio for photocurrent detection under reverse operation. Most importantly, however, the prior art devices consume much power, owing to the large driving voltages. An alternative device is therefore desired.

These and other objects are achieved according to the invention by a method described in the way introduction and further comprising the following steps:
applying, during an emission state (t1), a first driving signal (V1, J1) to said organic electroluminescent layer (1), said first driving signal being such that light is generated by and emitted from said organic electroluminescent layer (1), and
applying, during a sensing state (t2), a second driving signal (V2,J2) to said organic electroluminescent layer (1), said second driving signal being such that the power of said second driving signal has essentially a zero value for accurately detecting an electric current generated in said organic electroluminescent layer when said organic electroluminescent layer is hit by external light.

A highly economical driving method for a dual function organic device may be achieved thereby, by minimizing the power consumption of a display. The use of the invention in, for example, a cellular device increases the battery lifetime considerably.

Preferably, said second driving signal is a voltage applied across said organic electroluminescent layer, said voltage having a value of essentially 0 volts. A display without leakage currents is achieved thereby.

Alternatively, said second driving signal is a current density fed through said organic electroluminescent layer, said current density having a value of essentially 0 A/m². This enables a straightforward realization, since an organic display device is current-driven.

Preferably, the method further comprises the step of measuring, during said sensing state, one of the voltages across or the current through a load which is connected in series with said organic electroluminescent layer, thereby providing a measured value representing the signal being generated when a said organic electroluminescent layer is hit by a certain incident light power.

Moreover, the method suitably comprises the step of alternatingly driving said device in said emission state and said sensing state, the alternating states having respective durations of approximately 0-20 ms, thereby making it possible to integrate the method in an display device without the difference being perceivable by the human eye.

Furthermore, each of the electrodes 2,3 preferably has a work function, and the difference between the respective work functions is greater than 1 eV, preferably within the interval of 2-3.5 eV. By having a preferably large difference between said work functions, it is possible to achieve a good sensing in the sensing state as well as an optimum emission in the emission state of the display.

Moreover, the method suitably comprises the steps of:
comparing the measured value at two different moments,
transmitting, if the measured values differ from each other by more than a predetermined value, a switching signal to a determination device for setting said first driving voltage to an on or off state. This renders it possible to use the device, for example to display an image on a device, only when the lighting conditions of the display change, for example when a user takes the display out of a pocket to look at the display. The power consumption can thus be reduced as compared with a continuous display of the image.

Alternatively, the method further comprises the steps of:
measuring in said sensing state the power of incident light on at least a part of the device,
adjusting the emission of at least said part of the device in said emission state, based on the measured value of said incident power.

Thus, the method may be used, for example, to keep a device at a constant contrast ratio independently of the ambient lighting incident on the display.

According to yet another embodiment of the invention, the method further comprises the step of arranging an external light-emitting unit in the proximity of said device in order to be able to illuminate said display in order to generate an electric current through the display in said sensing state. The method may thus be used to generate an interactive display.

Finally, the method may further comprise the step of applying said electric current, generated in said sensing state, to a power storage unit, for powering the same, whereby the sensing state may be used, for example, to power the batteries of a portable device when hit by ambient light.

The above objects of the invention are also achieved by a dual-function light-emitting and light-sensing device, comprising
an organic electroluminescent layer, such as a polymer layer or a small-molecule compound layer,
means (2,3, 6) for applying to said electroluminescent layer alternatingly a first driving signal (V1, J1) for generating an emission state and a second driving signal (V2, J2) for generating a sensing state, the power of said second driving signal having essentially a zero value for accurately detecting an electric current generated in said organic electroluminescent layer when said organic electroluminescent layer is hit by external light.

A highly economical driving method for a dual-function organic device may be achieved thereby, by minimizing the power consumption of a display. The use of the invention in, for example, a cellular device increases the battery lifetime considerably.

Preferably, said second driving signal is a voltage applied across said organic electroluminescent layer, said voltage having a value of essentially 0 volts. A display without leakage currents is achieved thereby.

According to yet another embodiment of the invention, said second driving signal is a current fed through said organic electroluminescent layer, said current having a value of essentially 0 A/m². This enables a straightforward realization, since an organic display device is current-driven.

Preferably, the device further comprises a load which is connected in series with said organic electroluminescent layer, and means for measuring one of the voltages across or a current through said load during the sensing state, thereby providing a measured value representing the signal being generated when said organic electroluminescent layer is hit by a certain incident light power.

Suitably, the device is arranged to be alternately driven in said first and second state, the respective durations of said states being within the interval of 0-20 ms, which renders it possible to integrate the device in a display device without the difference being visible to the human eye.

Finally, said organic electroluminescent layer is preferably sandwiched between a first and a second electrode, each of the electrodes 2,3, having a work function, and the difference between said work functions being greater than 1 eV, preferably within the interval of 2-3.5 eV. Such a large difference between said work functions renders it possible to achieve a good sensing in the sensing state as well as an optimum emission in the emission state of the display.

The invention will be described in closer detail below with reference to the accompanying drawings.

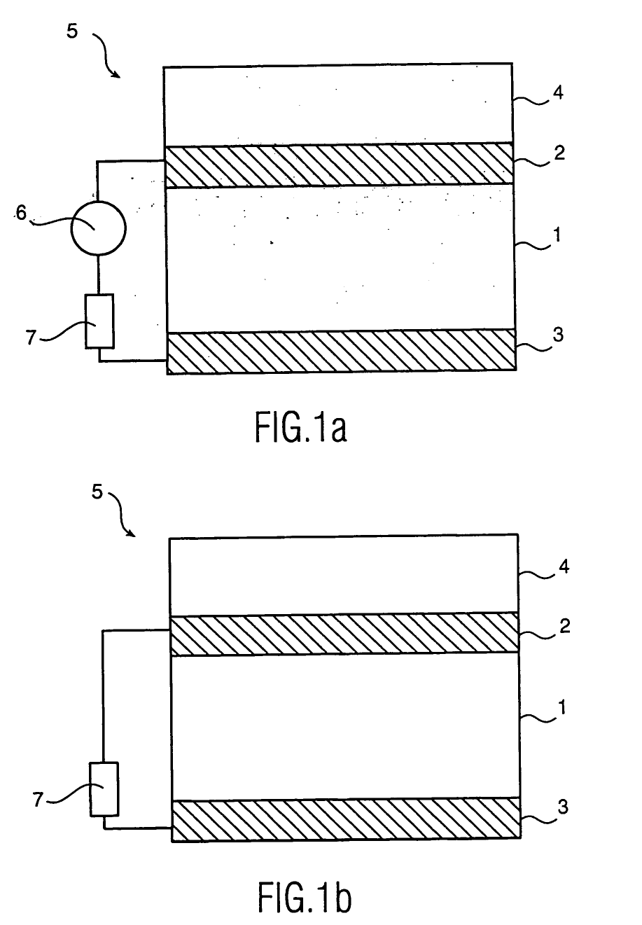

FIG. 1a is a schematic drawing of a dual-function photodiode in a light-emitting state.

FIG. 1b is a schematic drawing of a dual-function photodiode in a light-sensing state.

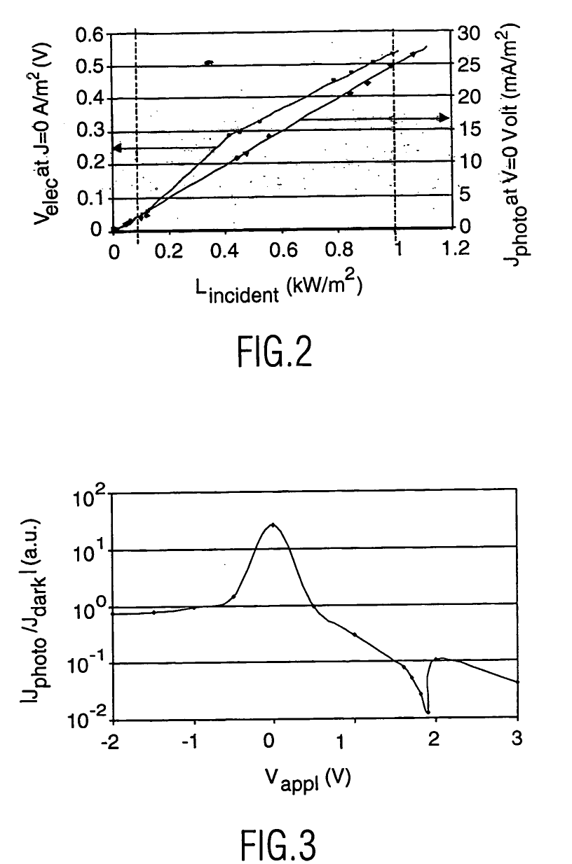

FIG. 2 is a diagram showing the current response to zero voltage driving (short-circuit configuration) and the voltage response to zero current driving (open-circuit configuration) as a function of the incident light.

FIG. 3 is a diagram showing the ratio between a photo-generated current density and a dark current density for zero voltage driving (short-circuit configuration).

As a photodiode, an electroluminescent polymer device has an intrinsic low efficiency, as is described in the prior art. The application of the polymer material in a photodiode is in direct competition with the emissive properties of the polymer material under forward operation. Increasing the photodiode efficiency by adding, for example, an acceptor has been proposed, but this will inevitably lead to a decrease of the emission efficiency under forward driving. However, this invention is based on the realization that even in a polymer material optimized for emission, the photo-current is sufficiently large to detect. This invention proposes two method of using a polymer LED device as a sensor with low power consumption and optimum signal-to-noise ratio. Furthermore, a plurality of specific applications of such a sensor are disclosed and discussed.

A dual-function photodiode, i.e. a light-emitting and light-sensing device as described herein, is schematically shown in FIG. 1a and FIG. 1b. Such a photodiode 5 comprises an active organic electroluminescent layer 1 of, for example, an electroluminescent polymer material, which is sandwiched between a first and a second electrode 2,3. The first electrode 2 functions as a so-called hole-injecting layer, and the second electrode 3 functions as a so-called electron-injecting layer. Furthermore, the photodiode may or may not comprise a front substrate 4, having the functions of stabilizing the photodiode and of separating the active photodiode parts from a potential user.

As was described above, the inventive photodiode has a dual function and may be driven in two modes or states.

In a light-emitting state t1 (FIG. 1a), a first driving signal, such as a first voltage V1, is applied across the organic electroluminescent layer 1 by means of a power source 6, whereby light is emitted from said organic electroluminescent layer 1. The first and the second electrode 2,3 described above have different work functions. An optimum charge injection into the polymer layer may be achieved thereby during the emission state, since the work function is a measure of the energy required to remove an electron from the surface of the first and the second electrode 2,3, respectively. The first electrode 2 (the hole-injecting layer) has a high work function (Φ₁˜5.2 eV), and this electrode is arranged to remove electrons from the valence states with high binding energy, leaving positive holes behind in these states. The second electrode 3 (the electron-injecting layer) has a low work function (Φ₂˜2 eV), and the electrons are loosely bound in the material. The work function difference is arranged to be larger than the band gap (i.e. the emission energy plus the Stokes shift) in order to get an optimum injection. The work function difference is accordingly dependent on the bad gap, and is approximately 2 eV for red and 3.2 eV for blue. In the present case, the anode-cathode combination described above has a work function difference of approximately 3.2 eV, which is sufficient to ensure optimum injection for all colors. Moreover, the work function difference may be greater than 3.0 eV in an embodiment of the invention in order to ensure optimum injection for blue materials. The second electrode is arranged to inject negatively charged electrons in the conduction states of the material, where the electrons also have a low binding energy. Under forward driving (where the first electrode is positive and the second electrode is negative), the holes and electrons moves towards each other, the electrons filling up the holes, and the increase in binding energy results in the release of a photon, i.e. light is emitted. When the device is driven in the light-emission state, a certain voltage, referred to as the built-in voltage of the device, needs to be applied before any current will start to flow through the device. After this built-in voltage V_{b-i} has been reached, the size of the current through the display will increase rapidly. The value of said built-in voltage is proportional to the difference between the work functions of the first and second electrodes.

In a photodiode state t2, also referred to as a sensing state (FIG. 1b), a second driving signal, such as a second voltage V2, is applied across the organic electroluminescent layer 1, said voltage being applied by the power source 6 or by means of a separate power source (not shown), and light incident on the layer 1 will give rise to the generation of a photocurrent Jₚₕₒₜₒ in the organic electroluminescent layer 1.

According to a first embodiment of this invention, said second driving signal is a voltage V2=0V (short-circuit configuration), i.e. a zero voltage is applied across the organic layer 1. In this state the two electrodes, now having the same potential, are separated by the insulating organic electroluminescent layer 1, for example a polymer layer. However, small leakage paths are always present in said layer, through which a small amount of charge is allowed to flow, provided there is a driving force. The above-described difference in work function between the first and the second electrode causes, electrons in the layer 1 to experience a high binding energy of the first electrode 2 and a low binding energy of the second electrode 3. Electrons will thus move from the second to the first electrode, and a small transient current (present during a short time only) will flow until an equilibrium state is reached. Initially both electrodes where neutral, but owing to said transient current the first electrode becomes negatively charged and the second electrode becomes positively charged, resulting in a negative field across the organic layer 1. As was indicated above, a zero applied voltage has advantages relating to the leakage current and the low power consumption necessary for the sensing state. At 0 V applied voltage, the electrodes 2,3 are set at the same voltage, and the leakage currents are accordingly forced to 0 since no external field is applied across the organic layer 1. However, the above transient current gives rise to a negative internal electric field which is used to drive a photo-current, generated as external light hits the device in the sensing state. In the above case, the size of the internal field is given by:
Eᵢₙₜ=V_{b-i}/t_{layer}
where Eᵢₙₜ is the internal field, V_{b-i} is the above built-in voltage, and t_{layer} is the thickness of the organic layer 1. When illuminating the device, electrons being in an valence state are excited to a conduction state, and the negative internal electric field breaks up the electron-hole pair, pulling the electron towards the second electrode 3 (the cathode) and the hole towards the first electrode 2 (the anode). Consequently, a small, measurable photocurrent is generated. Furthermore, since the built-in voltage V_{b-i} is proportional to the difference between the two work functions of the first and the second electrode, the internal electric field is also proportional to the work function difference, i.e. the larger the difference between the two work functions, the larger the internal electric field at 0 applied voltage. Moreover, a large work function difference is also required for an optimum emissive state, and a device is achieved thereby, which may be optimized for emission while still having an effective, power-efficient sensing state.

For present-day electrodes, the work function difference may be made large, resulting in high values of the built-in voltage V_{b-i} of between 1.4 and 3.1 volts. Moreover, it has been found that the optimum thickness of the organic layer 1 is in the interval between 60 and 90 nm, preferably about 70 nm, in order to achieve a high-efficiency emission state.

To make a comparison with prior art devices, the device in the cited U.S. Pat. No. 5,504,323 uses an A1 cathode and an ITO anode, resulting in a work function difference of approximately 0 V. The emission state cannot be an optimum then because high voltages are required, and moreover a negative bias needs to be applied across the organic layer in order to generate a sufficient field for breaking up the electron-hole pair as described above. Also, said negative bias results in a higher power consumption of the sensing state as well as a competition of the photo-current with an unstable leakage current.

The photo-current generated by the present invention may be measured, for example, by measuring the voltage drop across a measuring circuit 7 which is connected in series with the power source 6 between said first and second electrodes 2,3. An example of such a measuring circuit 7 comprises a high-ohmic resistor connected in parallel with an amplifier, both the resistor and the amplifier being connected in series with the organic electroluminescent layer. The voltage at the output of the amplifier is equal to the generated photocurrent multiplied by the parallel resistance. Moreover, a high input impedance device (such as a CMOS) is required because of the small current that is to be measured. The measured signal may subsequently be transmitted to a determination device (not shown) for determining a suitable value for the first driving signal, based on the incident light power. Consequently, as will be described below, the inventive device may be used for adjusting the light emitted by the display in the light-emitting state, based on information regarding the power of the incident light during the sensing state.

An important aspect of this invention is that the two states described above are temporally separated. In a passive matrix display, for example, each line is only addressed for a limited time period (typically 1/(N*frequency) seconds, where N is the total number of lines in the display and f is the refresh rate, typically 100 Hz). It may also be possible to measure the incident light (during the sensing state) within a smaller fraction of the time. This would make it possible to integrate the sensing state in an ordinary display device without this being noticeable to a potential user.

In a second embodiment of this invention (FIG. 1a), a first driving signal, here a first current density J1, is fed through the organic electroluminescent layer 1 in a first, light-emitting state t1, and a second driving signal, here a second sensing current density J2 in the second, sensing mode, is set to be zero, i.e. J2=0 [A/m2] (open-circuit configuration). While the second current J2 is fixed at 0 A/m2, the current through the organic electroluminescent layer 1 caused by incident light may be measured in a known manner. For the second embodiment, where the current through the electroluminescent layer is fixed, a voltage will appear under illumination and a leakage current will accordingly flow. Actually, the voltage that appears under illumination is the result of a direct competition between leakage current and photocurrent.

Both of the above sensing embodiments are highly economical when it comes to power consumption (the power P˜V·I˜0·I˜V·0˜0 W). Consequently, the inventive display is advantageously used, for example, in mobile applications, where power consumption is of great importance.

However, it may be shown that the open-circuit configuration has a slower response time than the short circuit configuration. The response time is an especially important property in interactive applications. The reason why the response time is of importance is that it is desirable to incorporate the sensor action in the multiplexed driving operation of the device. Simulations have demonstrated that the response time for a display utilizing a short-circuit configuration is of the order of 10 μs. This value is sufficiently small in order to integrate a sensing state in between emissive states as far as the amplification is concerned. Thus it is possible to achieve an emissive interactive display, having immediate feedback without noticeable interruption of the emission.

However, not all applications require such a fast response. A corresponding simulation for the second embodiment, i.e. the open-circuit embodiment, has given a response time of the order of 10 ms. The fast response is not required for the applications, as will be described below, as they may be solved in a different way in principle, because the fact that fast multiplexed sensing is not mandatory for measurements of the total amount of incident light.

Moreover, the short-circuit configuration exhibits a better photosignal-to-dark-current ratio, as is shown in FIG. 3, than does the open-circuit configuration, since there will always be leakage currents in the open-circuit configuration owing to the voltage that is applied across the organic layer 1. FIG. 3 shows the ratio between the photo-generated current density Jₚₕₒₜₒ and the dark current density J_{dark} for a device in short-circuit configuration as a function of the driving voltage Vₐₚₚₗ. It may be shown that this ratio is proportional to the signal-to-noise ratio. Clearly, a maximum can be found around zero volt. driving voltage. As the value of the photo-current density is of the same order of magnitude as for higher reverse voltages and the additional dark current is known to be unstable, the best signal-to-noise ratio is reached under zero volt driving conditions, i.e. the short-circuit configuration.

FIG. 2 shows the current response to the above zero voltage driving (short-circuit configuration) and the voltage response to the zero current driving (open-circuit configuration) as a function of the incident light. It is apparent from FIG. 2 that the current response Jₚₕₒₜₒ is linearly dependent on the incident light power L_{incident}, contrary to the corresponding voltage response V_{elec}. The reason for this is that, for the open-circuit embodiment, the maximum voltage that can be reached under illumination is equal to the built-in voltage of the device. The photosignal will therefore saturate already at relatively low illuminance levels. The photo-current on the other hand is shown to saturate at values higher by several orders of magnitude than the values found under 0 Volt driving in, for example, PCBM-doped systems. This difference between the two embodiments appears as a sub-linear dependence of the induced voltage compared to a linear dependence of the current on the illuminance, as is shown in FIG. 2. The short-circuit configuration is preferred for most practical applications in view of the above-described advantages.

A plurality of application examples of the inventive sensing display device will be described in closer detail below. A first application example, relating to intensity scaling, will first be described. As was noted above, it is possible to use the inventive method and device for generating a display using the measured photo-current for controlling the emission. An active feedback device is achieved thereby which may be used to decrease the power consumption of the display. It is thus possible to have different emissions from the display, based on the instantaneous illumination of the display, in order to achieve an acceptable contrast ratio of the display at all times. Previously, for a device without intensity scaling, a manufacturer had to implement a default value which was to give a sufficient contrast ratio under all circumstances, i.e. be enough even for unfavorable circumstances. The invention renders it possible to keep the contrast ratio at a constant value, or alternatively only to vary the contrast ratio between preset boundaries, thereby reducing the power consumption of the device.

A device with and a device without the inventive intensity scaling will be compared below. In this example a 70 nm thick organic layer (PPV) was used. Three typical illumination conditions are distinguished for the comparison:
i Outdoors on a cloudy day (10 k lux=3183 Cd/m²)
ii Indoors near window (1.5 k lux=477 Cd/m²)
iii Indoors far from window under strip lighting (300 lux=95 Cd/m²).

It is possible to calculate the contrast ratio for these conditions, namely: CRᵢ=1+0.0157×L^{int}_{PLEDmax}, CRᵢᵢ=1+0.105×L^{int}_{PLEDmax}, CRᵢᵢᵢ=1+0.526×L^{int}_{PLEDmax}. In this example we choose CRᵢ=10. This gives L^{int}_{PLEDmaxi}=573 Cd/m². At a multiplexing rate of 64, being a value typical of polymer LED displays, this gives a value of L^{intpulse}_{PLEDmaxi}=64×573=36700 Cd/m² during the application of the current pulse. This leads to CRᵢᵢ=60.2 and CRᵢᵢᵢ=301. Adjusting the light output so as to keep the CR ratio constant at a value of 10 will yield L^{intpulse}_{PLEDmaxii}=5490 Cd/m² and L^{intpulse}_{PLEDmaxiii}=1100 Cd/m².

The relation between the light output and the power consumption during operation must be known in order to make an estimate of the decrease in power consumption caused by the application of a sensory function. For the power consumption (P_{cons}) per square meter we can distinguish four contributions:
(1) Current through the polymer layer.
(2) A resistive loss due to PEDOT and the ITO leads.
(3) Charging of the capacitor in “on” and “off” states.
(4) Power dissipation in the current source.

It is then possible to calculate P_{cons}/m² for the three illumination conditions, resulting in: P_{cons}/m²|ᵢ=735 W/m², P_{cons}/m²|ᵢᵢ=88 W/m², P_{cons}/m²|ᵢᵢᵢ=29.5 W/m².

During the use of the display the three different conditions do not occur in equal fractions of the time. For Western Europe we may assume a tᵢ:tᵢᵢ:tᵢᵢᵢ time distribution of 10:10:80. We can now compare the difference in power consumption between a display with and a display without intensity scaling for a 5.4 cm² 64×96 matrix display. Without adjustment, the display consumes P_{cons}=397 mW while with adjustment it consumes P_{cons}=57 mW. In this example it is possible to decrease the power consumption of the display by a factor 7. This leads to a considerable increase of the operation time of the battery between loading sessions. These values are calculated for a somewhat extreme situation, however, it does indicate an order of magnitude of the improvement that is possible.

It is preferred to use a limited number of illumination levels rather than a continuous feedback system. By making sure that different standard situations correspond to the centers of the intervals chosen, one prevents rapid shifting between levels.

A more or less additional possibility of the sensing display according to the invention is to introduce a position-dependent emission intensity. When the ambient light has different intensities at different positions of the screen, the emission may also be varied over the screen in such a way as to maintain a constant CR at different positions of the display. It may even provide the user with some information on how to improve his or her perception of the display, for example with small arrows that show the user were to turn in order to decrease the incident light intensity.

The second application example, for example relating to the representation of a provider name on, for example, a cellular telephone unit, will be described below.

The low power consumption of passive LCD displays facilitated a fulfillment of the provider's demand to have their name represented on the display even when the display is not in use. For technologies with a distinctly higher power consumption, like organic LEDs and active matrix LCDs, this demand poses serious challenges. A prolonged representation of the provider's name will lead to a rapid exhaustion of the battery. Therefore, alternatives are needed to satisfy the telecommunication providers. One such alternative is to use two separate technologies, one for the actual display, and a standard passive reflective LCD for the provider representation. However, apart from the fact that part of the display area is lost, it is also not desirable to have two separate display technologies in one display. Another alternative is to display the provider's name only when there is actual activity around the device. The implementation of a motion detector is required for this.

The sensing ability of the polymer LED display may be used to detect changes in the direct environment of the display. This may be used, for example, as a switch for the provider name representation, but also for many other applications. The provider name representation can be turned “on” or “off” depending on the behavior of the ambient illumination in time. Whenever a change is detected, the provider name representation may be activated, and alternatively, when the situation has been constant for a certain amount of time, the provider name representation may be turned off again. In more or less the same way this motion detector may be used to de-activate the display when it is not used. It may automatically switch to a dormant state when no change is detected and finally switch itself off.

A third application example of this invention will now be described. Here, an external active lighting device is arranged, which may be used to communicate with a device based on the invention. The lighting device may be, for example, a light pen, which emits light at a certain wavelength (this may also be an organic light-emitting device). When such a lighting device is used for pointing at the display, the pointing position may be recognized by the sensing display and may thus be used as an alternative mouse device in acting as an interactive display device. As an example, a light pen may be used to “click” on icons on the display, and thereby provoke some action on the display. For prior art devices with high leakage currents, a situation may occur where a pixel in another “icon” at the same time has a high leakage current. Consequently, an action will take place other than the one desired. Such an interference is not possible with the inventive display in the short-circuit configuration, since there are no leakage currents in this case.

The above active lighting device may also be used to transfer data optically, and in this way a cellular telephone display may be used to load data, for example prices in a store. It may even be possible to load data in parallel in the case of a matrix display.

A fourth application example of this invention is to use the display device to charge the batteries that power, for example, a cellular telephone whenever light is incident on the display.

In summary, this invention provides for a dual-function organic device having a low power consumption in the sensing state. Moreover, in the preferred short-circuit condition, the leakage currents of the organic device are equal to zero. Therefore, their typical unstable behavior does not interfere with the sensing properties of the device. Furthermore, the invention is especially suitable for use in, for example, interactive devices (such as, for example, those using a light pen as described above) in which leakage current variations can lead to undesired results. It is to be noted that many variations and modifications of this invention are possible to those skilled in the art. For example, it is noted that the method and device according to the invention may be applied to a single-segment device (lighting device), a segmented device, or a matrix display. The invention may also be used in passive as well as active matrix configurations. It should be noted that “zero voltage” and “zero current” in this application are to be interpreted as denoting values which are substantially equal to zero.

1. A method of driving a dual-function light-emitting and light-sensing device (5) comprising an organic electroluminescent layer (1), such as a polymer layer or a small-molecule compound layer, which is sandwiched between a first and a second electrode (2, 3), comprising the following steps:
applying, during an emission state (t1), a first driving signal (V1, J1) to said organic electroluminescent layer (1), said first driving signal being such that light is generated by and emitted from said organic electroluminescent layer (1), and
applying, during a sensing state (t2), a second driving signal (V2,J2) to said organic electroluminescent layer (1), said second driving signal being such that the power of said second driving signal has essentially a zero value for accurately detecting an electric current generated in said organic electroluminescent layer when said organic electroluminescent layer is hit by external light.

2. A method as claimed in claim 1, wherein said second driving signal (V2) is a voltage applied across said organic electroluminescent layer (1), said voltage having a value of essentially 0 volts.

3. A method as claimed in to claim 1, wherein said second driving signal (J2) is a current density fed through said organic electroluminescent layer (1), said current density having a value of essentially 0 A/m².

4. A method as claimed in to claim 1, further comprising the step of:
measuring, during said sensing state (t2), one of the voltages (V2) across or the current density (J2) through a load (7) which is connected in series with said organic electroluminescent layer (1), thereby providing a measured value representing the signal being generated as said organic electroluminescent layer (1) is hit by a certain incident light power.

5. A method as claimed in to claim 1, further comprising the step of:
alternatingly driving said device (5) in said emission state (t1) and said sensing state (t2), the alternating states having respective durations of approximately 0 to 20 ms.

6. A method as claimed in to claim 1, wherein each of the electrodes (2,3), has a work function (Φ₁, Φ₂), and the difference between said work functions is greater than 1 eV, and preferably lies within an interval of 2 to 3.5 eV.

7. A method as claimed in to claim 4, further comprising the steps of:
comparing the measured value at two different moments,
transmitting a switching signal to a determination device for setting said first driving voltage to an on or off state if the measured values differ from each other by more than a predetermined value.

8. A method as claimed in claim 1, further comprising the steps of:
measuring the power of light incident on at least a part of the device in said sensing state,
adjusting the emission of at least said part of the device in said emission state, based on the measured value of said incident power.

9. A method as claimed in claim 1, further comprising the step of:
arranging an external light-emitting unit positioned in proximity of said device so as to be able to illuminate said display in order to generate an electric current through the display in said sensing state.

10. A method as claimed in claim 1, further comprising the step of:
applying said electric current generated in said sensing state to a power storage unit for powering said storage unit.

11. A dual-function light-emitting and light-sensing device (5), comprising
an organic electroluminescent layer (1), such as a polymer layer or a small-molecule compound layer,
means (2,3, 6) for applying to said electroluminescent layer alternatingly a first driving signal (V1, J1) for generating an emission state and a second driving signal (V2, J2) for generating a sensing state, the power of said second driving signal having essentially a zero value for accurately detecting an electric current generated in said organic electroluminescent layer when said organic electroluminescent layer is hit by external light.

12. A device as claimed in to claim 11, wherein said second driving signal (V2) is a voltage applied across said organic electroluminescent layer (1), said voltage having a value of essentially 0 volts.

13. A device as claimed in claim 11, wherein said second driving signal (J2) is a current density fed through said organic electroluminescent layer (1), said current density having a value of essentially 0 A/m².

14. A device as claimed in to claim 11, further comprising a load (7) which is connected in series with said organic electroluminescent layer, and means for measuring one of the voltages across or a current through said load during the sensing state, thereby providing a measured value representing the signal being generated as said organic electroluminescent layer is hit by a certain incident light power.

15. A device as claimed in claim 11, wherein the device is arranged to be alternatingly driven in said first and second state (t1, t2), the respective durations of said states lying within an interval of between 0 and 20 ms.

16. A device as claimed in claim 11, wherein said organic electroluminescent layer (1) is sandwiched between a first and a second electrode (2,3), each of the electrodes (2,3) has a work function (Φ₁, Φ₂), and the difference between said work functions is greater than 1 eV, preferably lying within an interval of 2 to 3.5 eV.
